(19) United States
(12) Patent Application Publication
(10) Pub. No.: US 2025/0048758 A1
(43) Pub. Date: Feb. 6, 2025

(54) SEMICONDUCTOR DEVICE, METHOD OF MANUFACTURING SEMICONDUCTOR DEVICE, AND IMAGING DEVICE

(71) Applicant: SONY SEMICONDUCTOR SOLUTIONS CORPORATION, KANAGAWA (JP)

(72) Inventor: YASUNORI SOGOH, KANAGAWA (JP)

(21) Appl. No.: 18/719,704

(22) PCT Filed: Nov. 15, 2022
(86) PCT No.: PCT/JP2022/042451

§ 371 Date: Jun. 13, 2024

(30) Foreign Application Priority Data
Dec. 22, 2021 (JP) 2021-208515

(51) Int. Cl. H01L 27/146

(52) U.S. Cl. CPC H01L 27/14612; H01L 27/14689

(57) ABSTRACT

To provide a semiconductor device configured to suppress impurities from diffusing in a lateral direction, a method of manufacturing the semiconductor device, and an imaging device in which the semiconductor device is used. The semiconductor device includes a semiconductor substrate, and a field effect transistor provided on a first main surface side of the semiconductor substrate. The field effect transistor includes an N-type region provided on the first main surface side of the semiconductor substrate and serving as at least a part of a source region or at least a part of a drain region, an insulating film provided on the N-type region, and an N-type semiconductor layer provided on the N-type region via the insulating film.

### TECHNICAL FIELD

The present disclosure relates to a semiconductor device, a method of manufacturing a semiconductor device, and an imaging device.

### BACKGROUND ART

A non-planar transistor having a vertical gate electrode and a channel is known as a semiconductor device used in Complementary Metal Oxide Semiconductor (CMOS) image sensors (see PTL 1, for example).

A MOS transistor (FinFET) with a groove-gate structure is also known as the semiconductor device used in CMOS image sensors (see PTL 2, for example).

### CITATION LIST

### Patent Literature

### [PTL 1]

JP 2006-121093A

### [PTL 2]

JP 2021-15891A

### SUMMARY

### Technical Problem

By forming a source region and a drain region deeply in a FinFET, noise characteristics of pixels can be improved. However, when impurities are ion-implanted deeply in order to form a source region and a drain region, diffusion of the impurities in the lateral direction becomes significant. Consequently, short-channel effects occur, possibly resulting in a reduced effective gate length. Furthermore, if the diffusion of impurities in the lateral direction is significant, it could become difficult to form source and drain regions of high impurity concentration, and it could become difficult to reduce contact resistances of the source and drain regions respectively.

The present disclosure has been achieved in view of the circumstances described above, and an object of the present disclosure is to provide a semiconductor device configured to suppress impurities from diffusing in a lateral direction, a method of manufacturing the semiconductor device, and an imaging device in which the semiconductor device is used.

### Solution to Problem

A semiconductor device according to one aspect of the present disclosure includes a semiconductor substrate, and a field effect transistor provided on a first main surface side of the semiconductor substrate. The field effect transistor includes an N-type region provided on the first main surface side of the semiconductor substrate and serving as at least a part of a source region or at least a part of a drain region, an insulating film provided on the N-type region, and an N-type semiconductor layer provided on the N-type region via the insulating film.

Thus, when manufacturing the field effect transistor, solid-phase diffusion of N-type impurities from the N-type semiconductor layer to the semiconductor substrate via the insulating film occurs, whereby the N-type region can be formed. Since the solid-phase diffusion allows for the formation of a thin N-type region, a semiconductor device that is configured to suppress the N-type impurities from diffusing in the lateral direction can be provided.

A method of manufacturing a semiconductor device according to one aspect of the present disclosure includes the steps of: forming an insulating film on a semiconductor substrate; forming an N-type semiconductor layer on the insulating film; and heat-treating the semiconductor substrate on which the N-type semiconductor layer is formed, and diffusing N-type impurities in solid phase from the N-type semiconductor layer to the semiconductor substrate, to form an N-type region serving as at least a part of a source region or at least a part of a drain region.

Thus, the N-type region can be formed by the solid-phase diffusion of the N-type impurities from the N-type semiconductor layer to the semiconductor substrate via the insulating film. By introducing the N-type impurities by solid-phase diffusion instead of ion-implantation, the N-type region can be formed thinly, and diffusion of the N-type impurities in the lateral direction can be suppressed.

An imaging device according to one aspect of the present disclosure includes a photoelectric conversion element and a semiconductor device for reading an electric charge obtained through photoelectric conversion by the photoelectric conversion element. The semiconductor device includes a semiconductor substrate, and a field effect transistor provided on a first main surface side of the semiconductor substrate. The field effect transistor includes an N-type region provided on the first main surface side of the semiconductor substrate and serving as at least a part of a source region or at least a part of a drain region, an insulating film provided on the N-type region, and an N-type semiconductor layer provided on the N-type region via the insulating film.

Thus, a semiconductor device configured to suppress N-type impurities from diffusing in the lateral direction can be used as the semiconductor device for reading an electric charge obtained through photoelectric conversion by the photoelectric conversion element. As a result, the readout performance of the imaging device can be improved.

### BRIEF DESCRIPTION OF DRAWINGS

FIG. 1 is a plan view schematically showing a configuration example of a semiconductor device according to Embodiment 1 of the present disclosure.

FIG. 2 is a cross-sectional view schematically showing a configuration example of the semiconductor device according to Embodiment 1 of the present disclosure.

FIG. 3 is a cross-sectional view schematically showing a configuration example of the semiconductor device according to Embodiment 1 of the present disclosure.

FIG. 4A is a cross-sectional view sequentially showing the steps of a method of manufacturing a semiconductor device according to Embodiment 1 of the present disclosure.

FIG. 4B is a cross-sectional view sequentially showing the steps of the method of manufacturing a semiconductor device according to Embodiment 1 of the present disclosure.

FIG. 4C is a cross-sectional view sequentially showing the steps of the method of manufacturing a semiconductor device according to Embodiment 1 of the present disclosure.

FIG. 4D is a cross-sectional view sequentially showing the steps of the method of manufacturing a semiconductor device according to Embodiment 1 of the present disclosure.

FIG. 4E is a cross-sectional view sequentially showing the steps of the method of manufacturing a semiconductor device according to Embodiment 1 of the present disclosure.

FIG. 4F is a cross-sectional view sequentially showing the steps of the method of manufacturing a semiconductor device according to Embodiment 1 of the present disclosure.

FIG. 4G is a cross-sectional view sequentially showing the steps of the method of manufacturing a semiconductor device according to Embodiment 1 of the present disclosure.

FIG. 4H is a cross-sectional view sequentially showing the steps of the method of manufacturing a semiconductor device according to Embodiment 1 of the present disclosure.

FIG. 5 is a plan view schematically showing the positional relationship between an opening portion formed in a step shown in FIG. 4E and a gate electrode.

FIG. 6 is a graph showing a diffusion length of N-type impurities obtained when arsenic (As) is diffused in solid phase from an N+ type semiconductor layer to a semiconductor region (example).

FIG. 7 is a graph showing a diffusion length of N-type impurities obtained when the N-type impurities are thermally diffused by ion implantation (comparative example).

FIG. 8 is a plan view schematically showing a configuration example of a semiconductor device according to Embodiment 2 of the present disclosure.

FIG. 9 is a cross-sectional view schematically showing a configuration example of the semiconductor device according to Embodiment 2 of the present disclosure.

FIG. 10 is a cross-sectional view schematically showing a configuration example of the semiconductor device according to Embodiment 2 of the present disclosure.

FIG. 11A is a cross-sectional view sequentially showing the steps of a method of manufacturing a semiconductor device according to Embodiment 2 of the present disclosure.

FIG. 11B is a cross-sectional view sequentially showing the steps of the method of manufacturing a semiconductor device according to Embodiment 2 of the present disclosure.

FIG. 11C is a cross-sectional view sequentially showing the steps of the method of manufacturing a semiconductor device according to Embodiment 2 of the present disclosure.

FIG. 11D is a cross-sectional view sequentially showing the steps of the method of manufacturing a semiconductor device according to Embodiment 2 of the present disclosure.

FIG. 11E is a cross-sectional view sequentially showing the steps of the method of manufacturing a semiconductor device according to Embodiment 2 of the present disclosure.

FIG. 11F is a cross-sectional view sequentially showing the steps of the method of manufacturing a semiconductor device according to Embodiment 2 of the present disclosure.

FIG. 12 is a plan view schematically showing the positional relationship among a recess portion (recess pattern) formed in a step shown in FIG. 11C, an opening portion formed in a step shown in FIG. 11D, and a gate electrode.

FIG. 13 is a schematic diagram showing a configuration example of an imaging device according to Embodiment 3 of the present disclosure.

FIG. 14 is a circuit diagram showing a configuration example of a pixel unit according to Embodiment 3 of the present disclosure.

FIG. 15 is a plan view schematically showing the positional relationship between the opening portion and the gate electrode that is obtained when a MOS transistor described in Embodiment 1 is used as a transfer transistor of a pixel unit PU.

### DESCRIPTION OF EMBODIMENTS

Embodiments of the present disclosure will be described below with reference to the drawings. In descriptions of the drawings referred to in the following descriptions, same or similar portions will be denoted by the same or similar reference signs. However, it should be noted that the drawings are schematic, and the relationships between thicknesses and planar dimensions, ratios of thicknesses of respective layers, and the like are different from the actual ones. Therefore, specific thicknesses and dimensions should be determined by considering the following descriptions. In addition, needless to say, the drawings include portions where mutual dimensional relationships and ratios differ between the drawings.

It is to be understood that the definitions of directions such as upward and downward in the following descriptions are merely definitions provided for the convenience of explanation and are not intended to limit the technical ideas of the present disclosure. For example, it is obvious that when an object is rotated 90 degrees and observed, the top and bottom are converted into and interpreted as the left and right, and when the object is rotated 180 degrees and observed, the top and bottom are interpreted as being inverted.

In the following descriptions, the terms “X-axis direction,” “Y-axis direction,” and “Z-axis direction” may be used to describe directions. For example, the X-axis direction and the Y-axis direction are directions parallel to a front surface 2a of a semiconductor substrate 2. The X-axis direction and the Y-axis direction are also referred to as “horizontal directions.” The Z-axis direction is a direction which intersects vertically with the front surface 2a of the semiconductor substrate 2. The Z-axis direction is also referred to as “depth direction.” The X-axis direction, the Y-axis direction, and the Z-axis direction are directions orthogonal to each other.

In the following descriptions, the + sign added to p or n indicating the conductivity type of a semiconductor represents a relatively higher impurity concentration compared to a semiconductor without the + sign. However, semiconductors with an identical p (or n) do not mean that these semiconductors have exactly the same impurity concentration.

### Embodiment 1

### (Example of Configuration of Semiconductor Device)

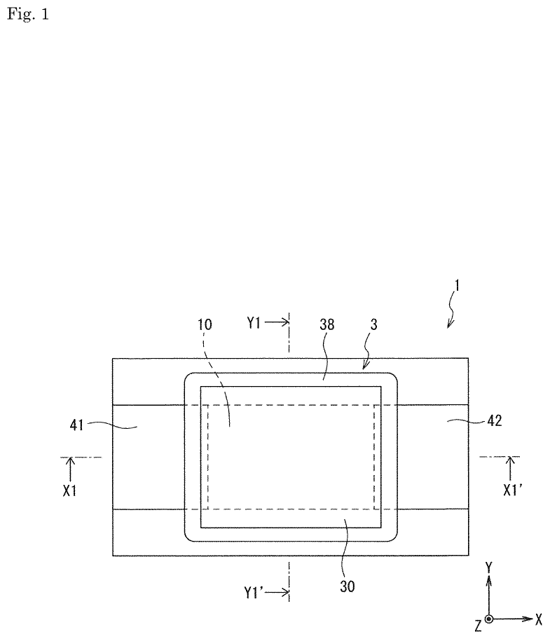

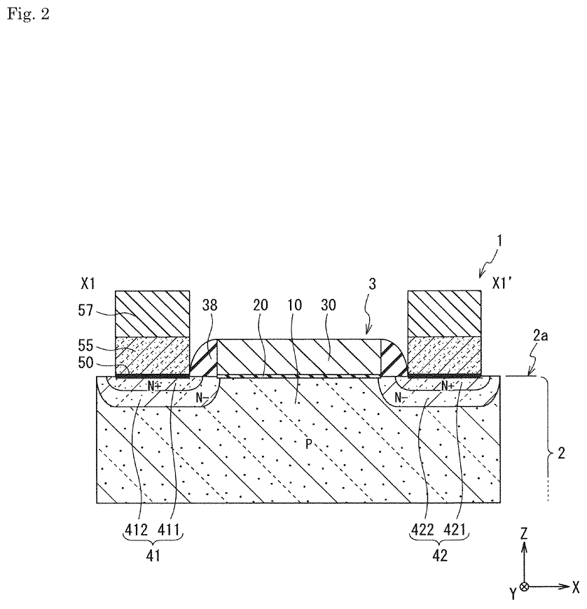

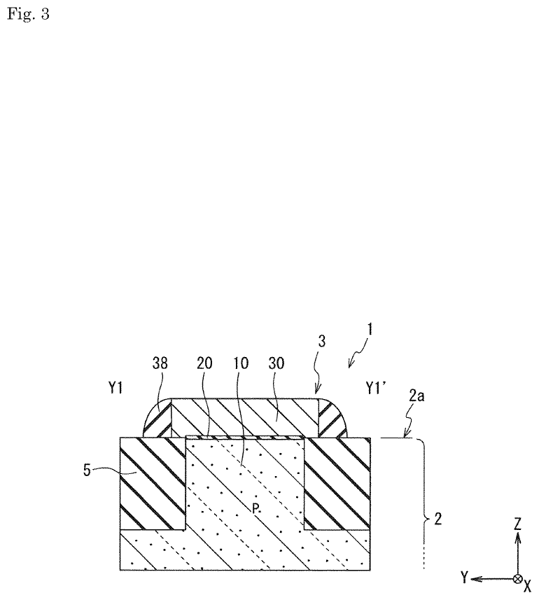

FIG. 1 is a plan view schematically showing a configuration example of a semiconductor device 1 according to Embodiment 1 of the present disclosure. FIGS. 2 and 3 are cross-sectional views schematically showing a configuration example of the semiconductor device 1 according to Embodiment 1 of the present disclosure. FIG. 2 shows a cross section of the plan view shown in FIG. 1, taken along line X1-X1′. FIG. 3 shows a cross section of the plan view shown in FIG. 1, taken along line Y1-Y1′. Note that FIG. 1 omits the illustration of an N-type semiconductor layer 55 and a contact electrode 57 shown in FIG. 2.

As shown in FIGS. 1 to 3, the semiconductor device 1 according to Embodiment 1 includes a semiconductor substrate 2, an N-type Metal Oxide Semiconductor (MOS) transistor 3 (an example of “field effect transistor” of the present disclosure) provided in the semiconductor substrate 2, and an element separation layer 5 provided in the semiconductor substrate 2.

The semiconductor substrate 2 is composed of, for example, single-crystal silicon. The semiconductor substrate 2 has the front surface 2a (an example of “first main surface” of the present disclosure), and a rear surface 2b located on the opposite side of the front surface 2a. The MOS transistor 3 is provided on the front surface 2a side of the semiconductor substrate 2. The element separation layer 5 is an insulating film for electrically separating elements adjacent in the horizontal direction, and is composed of, for example, a silicon oxide film (SiO₂ film) embedded in a trench.

The MOS transistor 3 has a P-type semiconductor region 10 in which a channel is formed, a gate insulating film 20, a gate electrode 30, a sidewall insulating film 38 provided on a side surface of the gate electrode 30, a source region 41 and a drain region 42 provided in the semiconductor substrate 2, an insulating film 50 provided on each of the source region 41 and the drain region 42, and an N-type semiconductor layer 55 provided on each of the source region 41 and the drain region 42 via the insulating film 50. The N-type semiconductor layer 55 covers at least a part of the sidewall insulating film 38.

The semiconductor region 10 is a part of the semiconductor substrate 2, for example, and is composed of single-crystal silicon. For example, the semiconductor region 10 is a P-type well region that is formed by ion implantation and thermal diffusion of P-type impurities such as boron (B) in the N-type semiconductor substrate 2.

The gate insulating film 20 is provided so as to cover a top surface of the semiconductor region 10. The top surface of the semiconductor region 10 is a part of the front surface 2a of the semiconductor substrate 2. The gate insulating film 20 is composed of, for example, a SiO₂ film.

The gate electrode 30 covers the semiconductor region 10 over the gate insulating film 20. For example, the gate electrode 30 is arranged so as to face the top surface of the semiconductor region 10 via the gate insulating film 20.

The source region 41 is provided on and near the front surface 2a of the semiconductor substrate 2. The source region 41 is connected to one side of the semiconductor region 10 in the X-axis direction. The drain region 42 is provided on and near the front surface 2a of the semiconductor substrate 2. The drain region 42 is connected to the other side of the semiconductor region 10 in the X-axis direction. The source region 41 and the drain region 42 are of N-type, for example.

The source region 41 has an N+ type region 411 (an example of “N-type region” of the present disclosure), and an N− type region 412 located around the N+ type region 411. The drain region 42 has an N+ type region 421 (an example of “N-type region” of the present disclosure), and an N− type region 422 located around the N+ type region 421.

The insulating film 50 is, for example, a silicon nitride film (SiN film) or a silicon oxide film (SiO₂ film). The thickness of the insulating film 50 is, for example, 5 Å or more and 15 Å or less.

The N-type semiconductor layer 55 is, for example, polysilicon, amorphous silicon, or SiGe. Also, the concentration of N-type impurities in the N-type semiconductor layer 55 is, for example, 1×10²⁰/cm³ or more. Examples of the N-type impurities included in the N-type semiconductor layer 55 include arsenic (As), phosphorous (P), or both.

The contact electrode 57 is provided on the N-type semiconductor layer 55. The contact electrode 57 is composed of, for example, a barrier metal such as a conductive material, and tungsten (W). The tungsten (W) is ohmically connected to the N-type semiconductor layer 55 via the barrier metal.

As will be described later, the N+ type region 411 of the source region 41 of the MOS transistor 3 and the N+ type region 421 of the drain region 42 are formed by solid-phase diffusion of the N-type impurities from the N-type semiconductor layer 55 to the semiconductor substrate 2 via the insulating film 50. The peak concentrations of the N-type impurities in the N+ type regions 411, 421 are 1×10²⁰/cm³ or more. Thus, the N-type semiconductor layer 55 is ohmically connected to each of the N+ type regions 411, 421 via the insulating film 50.

As described above, ohmic connection is made between the contact electrode 57 and the N-type semiconductor layer 55, and ohmic connection is made also between the N-type semiconductor layer 55 and the N+ type regions 411, 421. Therefore, ohmic connections are made between the contact electrode 57 and the N+ type region 411 and between the contact electrode 57 and the N+ type region 421.

Furthermore, end portions (bottom portions) of the N+ type regions 411, 421 where the concentration of the N-type impurities is 1×10¹⁷/cm³ or less are present within 0.1 μm from the front surface 2a of the semiconductor substrate 2. That is, the depth of the N+ type regions 411, 421 from the front surface 2a is 0.1 μm or less. The N+ type regions 411, 421 are formed very thinly in the vicinity of the front surface 2a of the semiconductor substrate 2.

### (Method of Manufacturing Semiconductor Device)

The steps of a method of manufacturing the semiconductor device 1 according to Embodiment 1 of the present disclosure will be sequentially described next. The semiconductor device 1 is manufactured using various devices such as a chemical vapor deposition (CVD) device, an atomic layer deposition (ALD) device (including a sputtering device), an etching device, a heat treatment device, an ion implantation device, and a chemical mechanical polishing (CMP) device. Hereinafter, these devices are collectively referred to as a manufacturing device.

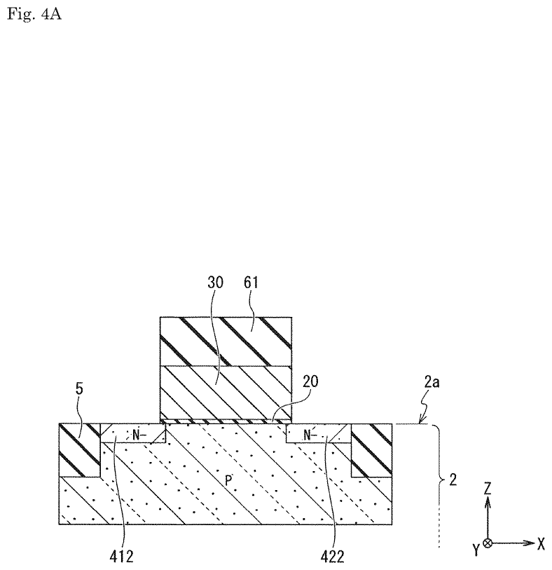

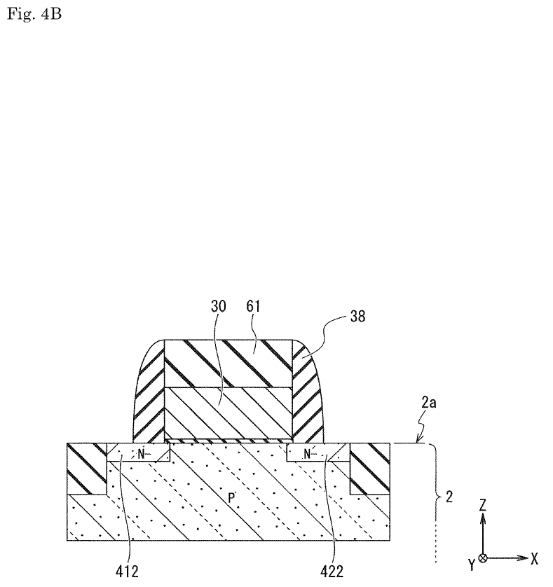

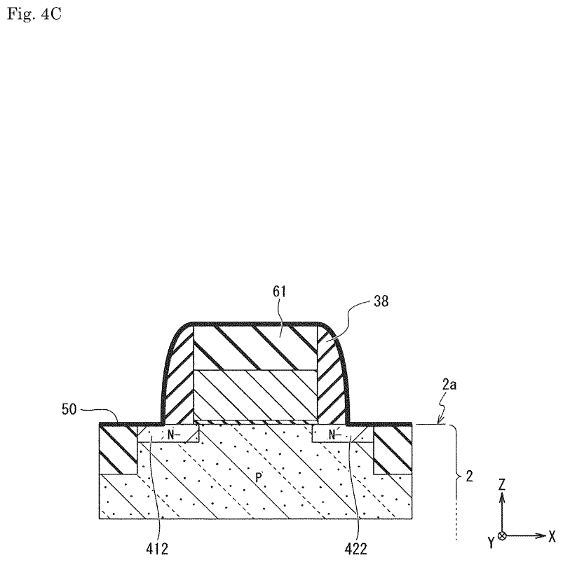

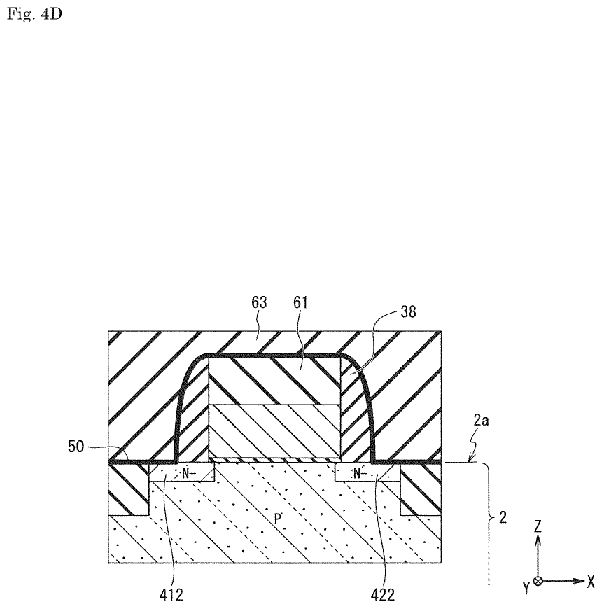

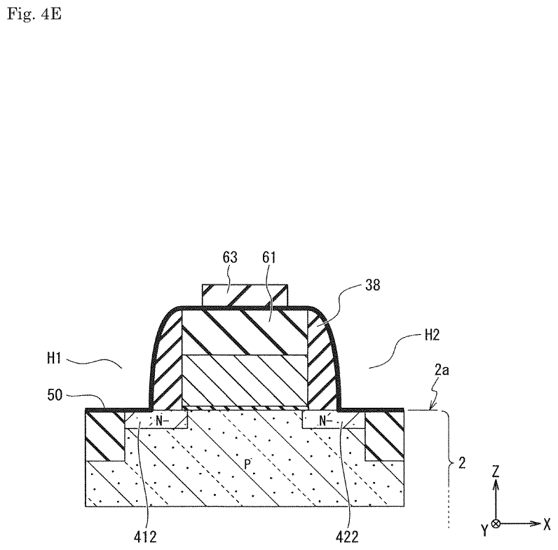

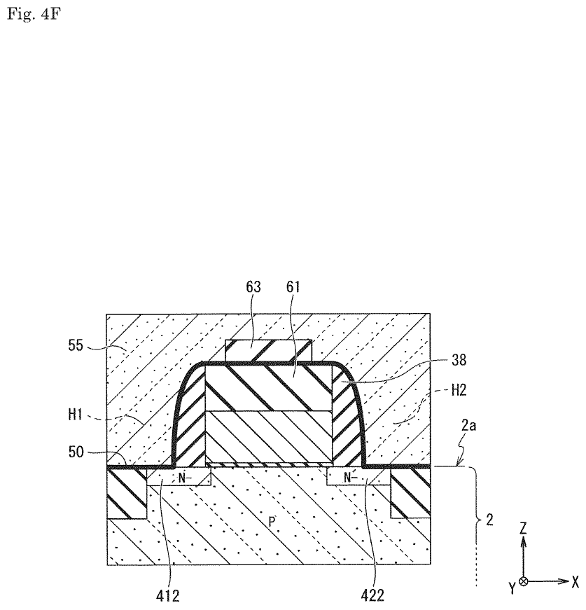

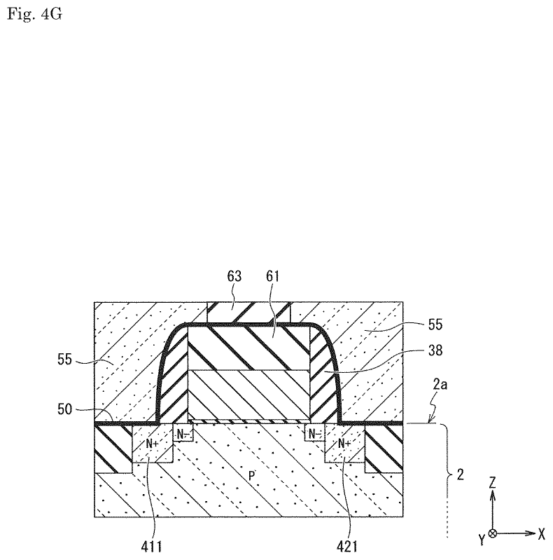

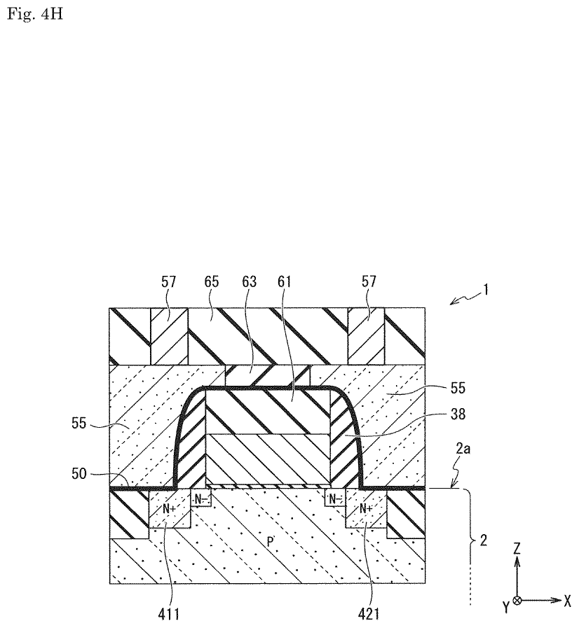

FIGS. 4A to 4H are cross-sectional views sequentially showing the steps of the method of manufacturing the semiconductor device 1 according to Embodiment 1 of the present disclosure. Each of the cross sections shown in FIGS. 4A to 4H corresponds to an X1-X1′ cross section (X-Z cross section) shown in FIG. 2.

In FIG. 4A, the manufacturing device forms a P-type well region in the semiconductor substrate 2, forms the element separation layer 5, thereafter thermally oxidizes the front surface 2a of the semiconductor substrate 2, and forms the gate insulating film 20. Next, the manufacturing device uses a CVD method to form a polysilicon film on the gate insulating film 20. Next, the manufacturing device forms a hard mask 61 on the polysilicon film. The hard mask 61 has a shape that covers the region where the gate electrode 30 is formed, but is open in the other regions. The hard mask 61 is composed of, for example, a SiO₂ film.

Next, the manufacturing device removes the polysilicon film through etching, by using the hard mask 61 as a mask. As a result, the manufacturing device forms the gate electrode 30.

Next, the manufacturing device ion-implants the N-type impurities such as phosphorous (P) or arsenic (As) on the front surface 2a side of the semiconductor substrate 2 by using the hard mask 61 as a mask. After the ion-implantation, the semiconductor substrate 2 is heat-treated, and the ion-implanted N-type impurities are activated. As a result, the N− type region 412 of the source region 41 and the N− type region 422 of the drain region 42 are formed in self-alignment with respect to the gate electrode 30. Note that the heat treatment for forming the N− type regions 412, 422 may not be performed at that moment but may be performed concurrently with heat treatment in the subsequent step (e.g., heat treatment for forming the N+ type regions 411, 412).

Next, the manufacturing device deposits the SiO₂ film and SiN film sequentially by means of, for example, the CVD method, and etches back the deposited films. Consequently, as shown in FIG. 4B, the sidewall insulating film 38 is formed on the side surface of the gate electrode 30.

Next, as shown in FIG. 4C, the manufacturing device forms the insulating film 50 on the front surface 2a of the semiconductor substrate 2. For example, the manufacturing device forms the insulating film 50 into a thickness of 5 Å or more and 15 Å or less by means of an ALD method. The insulating film 50 is a SiN film or a SiO₂ film. The insulating film 50 is provided continuously on the front surface 2a of the semiconductor substrate 2, the sidewall insulating film 38, and the hard mask 61.

Next, as shown in FIG. 4D, the manufacturing device forms a first interlayer insulating film 63 on the front surface 2a of the semiconductor substrate 2 by the CVD method. Next, the manufacturing device forms a resist pattern (not shown) on the first interlayer insulating film 63, and etches the first interlayer insulating film 63, with the resist pattern as a mask. Accordingly, as shown in FIG. 4E, in the first interlayer insulating film 63, the manufacturing device forms opening portions H1, H2 opening the N− type regions 412, 422.

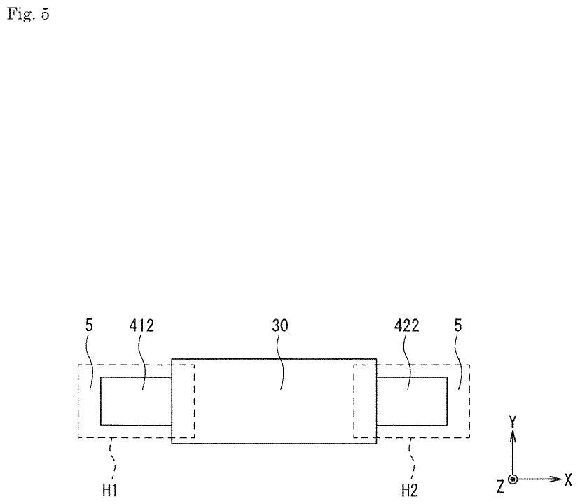

FIG. 5 is a plan view schematically showing the positional relationship between the opening portions H1, H2 formed in the step shown in FIG. 4E and the gate electrode 30. As shown in FIGS. 4E and 5, the opening portions H1, H2 are formed in self-alignment with respect to the gate electrode 30.

Next, as shown in FIG. 4F, the manufacturing device deposits the N-type semiconductor layer 55 doped with the N-type impurities over the entire upper part of the front surface 2a of the semiconductor substrate 2 by the CVD method, to fill the opening portions H1, H2. As described above, the N-type semiconductor layer 55 is, for example, polysilicon, amorphous silicon, or SiGe. Also, the concentration of the N-type impurities in the N-type semiconductor layer 55 is, for example, 1×10²⁰/cm³ or more. Examples of the N-type impurities included in the N-type semiconductor layer 55 include arsenic (As), phosphorous (P), or both.

Next, the manufacturing device heat-treats the N-type semiconductor layer 55 and the semiconductor substrate 2 (i.e., the entire substrate), and diffuses the N-type impurities in solid phase from the N-type semiconductor layer 55 to the semiconductor substrate 2 via the insulating film 50. The conditions for the heat treatment are, for example, that the heat treatment temperature is 1015° C. and the heat treatment duration is 10 minutes. Thus, as shown in FIG. 4G, the manufacturing device forms the N+ type region 411 of the source region 41 and the N+ type region 421 of the drain region 42.

Next, the manufacturing device etches back the N-type semiconductor layer 55. Accordingly, the N-type semiconductor layer 55 is separated into a section connected to the N+ type region 411 (also referred to as a source pad hereinafter) and a section connected to the N+ type region 412 (also referred to as a drain pad hereinafter).

Next, as shown in FIG. 4H, the manufacturing device forms a second interlayer insulating film 65 over the entire upper part of the front surface 2a of the semiconductor substrate 2 by the CVD method. Next, the manufacturing device forms a resist pattern (not shown) on the second interlayer insulating film 65, and etches the second interlayer insulating film 65, with the resist pattern as a mask. Accordingly, in the second interlayer insulating film 65, the manufacturing device forms an opening portion opened on the source pad (also referred to as a source opening portion hereinafter) and an opening portion opened on the drain pad (also referred to as a drain opening portion hereinafter).

Next, the manufacturing device sequentially deposits the barrier metal and tungsten (W) over the entire upper part of the front surface 2a of the semiconductor substrate 2 by means of, for example, the CVD method or a sputtering method, to fill the source opening portion and the drain opening portion.

Next, the manufacturing device performs CMP treatment on the tungsten (W) film to expose the second interlayer insulating film 65 from below the tungsten (W) film. Accordingly, the manufacturing device forms the contact electrode 57 on each of the source pad and the drain pad. The semiconductor device 1 according to Embodiment 1 is completed through the steps described above.

### (Diffusion Length)

The present disclosing party performed an experiment for comparing the diffusion length of the N-type impurities diffused in solid phase with the diffusion length of the ion-implanted N-type impurities.

### (1) Example

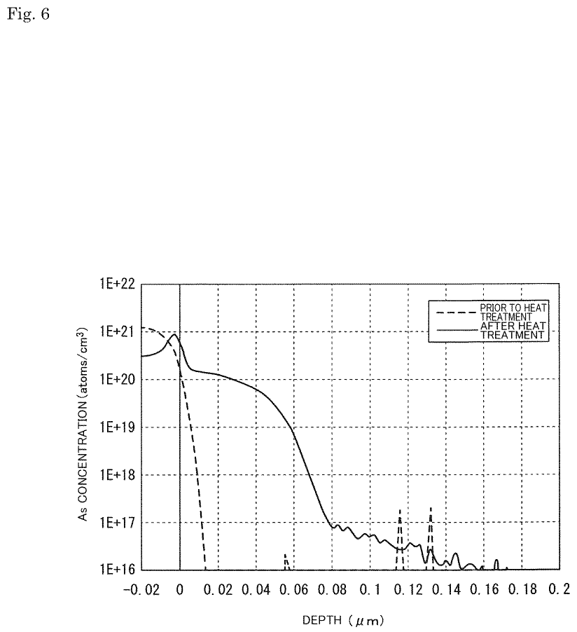

FIG. 6 is a graph showing the diffusion length of the N-type impurities obtained when arsenic (As) is diffused in solid phase from an N+ type semiconductor layer to the semiconductor region (example). In FIG. 6, the vertical axis shows the depth from a front surface of a silicon (Si) substrate, and the vertical axis shows the concentration of the arsenic (As). On the horizontal axis, 0 indicates the front surface of the Si substrate.

The present disclosing party prepared a sample in which a SiN film having a thickness of 10.5 Å was deposited on the front surface of the Si substrate and polysilicon doped with As was deposited. The present disclosing party heat-treated this sample at 1015° C. for 10 minutes, and evaluated the diffusion concentration and the diffusion length of the As by means of secondary ion mass spectrometry (SIMS) evaluation. As shown in FIG. 6, as a result of the heat treatment, it was confirmed that the As in the Si substrate diffused in the depth direction of the Si substrate. The peak concentration of the As after the heat treatment was confirmed to be 1×10²⁰/cm³ in the vicinity of the front surface of the Si substrate. Furthermore, the depth where the As concentration was 1×10¹⁷/cm³ (i.e., the diffusion length) was located 0.08 μm from the front surface of the Si substrate. According to this result, it was confirmed in the example that a steep, high-dose profile could be formed.

That is, it was confirmed that a diffusion profile in which the peak concentration of the N-type impurities was 1×10²⁰/cm³ or more and the minimum concentration of the N-type impurities was 1×10¹⁷/cm³ could be formed at the depth within 0.1 μm from the front surface of the Si substrate.

### (2) Comparative Example

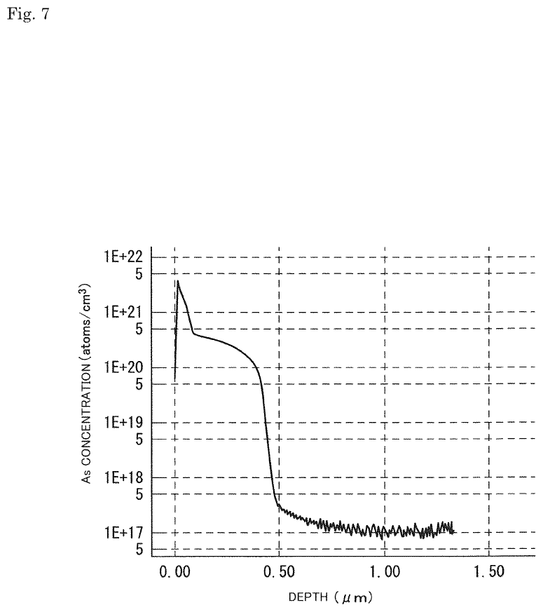

FIG. 7 is a graph showing a diffusion length of N-type impurities obtained when the N-type impurities are thermally diffused by ion implantation (comparative example). In FIG. 7, the vertical axis shows the depth from a front surface of a silicon (Si) substrate, and the vertical axis shows the concentration of the arsenic (As). As the comparative example, the present disclosing party prepared a sample in which arsenic (As) was ion-implanted into the front surface of the Si substrate. The conditions for the ion implantation are that the implantation energy is 5 keV and the dose amount is high (3×10¹⁵/cm²). The present disclosing party heat-treated this sample at 1000° C. for 10 seconds (RTA) and evaluated the diffusion concentration and diffusion length of the As by means of SIMS evaluation.

As shown in FIG. 7, the profile is a high-dose profile in which the As concentration in the vicinity of the front surface of the Si substrate is 1×10²¹/cm³, the depth at which the As concentration is 1×10¹⁷/cm³ (i.e., diffusion length) is deeper than 0.5 μm from the front surface of the Si substrate.

### (3) Evaluation Results

The comparative example described above shows a lower heat treatment temperature and a sufficiently shorter heat treatment duration as compared to the example. The heat treatment temperature in the example is 1015° C., whereas the heat treatment temperature in the comparative example is 1000° C. The heat treatment duration in the example is 10 minutes, whereas the heat treatment duration in the comparative example is 10 seconds. Although the comparative example had a sufficiently smaller thermal history than the example, the diffusion length in the comparative example was longer. The diffusion length in the example was 0.08 μm, whereas the diffusion length in the comparative example was 0.5 μm or more. These results confirmed that the diffusion length was suppressed more in the example than the comparative example. It was confirmed that the diffusion length in the example was suppressed to approximately ⅕ of the diffusion length in the comparative example.

Note that although FIGS. 6 and 7 show the diffusion lengths in the depth direction of the Si substrate, the diffusion lengths in the horizontal direction of the Si substrate are considered to show the same tendency as that in the depth direction.

### Advantageous Effects of Embodiment 1

As described thus far, the semiconductor device 1 according to Embodiment 1 of the present disclosure includes the semiconductor substrate 2, and the MOS transistor 3 provided on the front surface 2a side of the semiconductor substrate 2. The MOS transistor 3 is provided on the front surface 2a side of the semiconductor substrate 2, and includes the N+ type regions 411, 421 serving as at least a part of the source region 41 or at least a part of the drain region 42, the insulating film 50 provided on the N+ type regions 411, 421, and the N-type semiconductor layer 55 provided on the N+ type regions 411, 421 via the insulating film 50.

Thus, when manufacturing the MOS transistor 3, solid-phase diffusion of the N-type impurities (e.g., arsenic (As), phosphorous (P), or both) from the N-type semiconductor layer 55 into the semiconductor substrate 2 via the insulating film 50 occurs, whereby the N+ type regions 411, 421 can be formed. Since the solid-phase diffusion allows for the formation of the thin N+ type regions 411, 421, the semiconductor device 1 that is configured to suppress the N-type impurities from diffusing in the lateral direction can be provided.

The method of manufacturing the semiconductor device 1 according to Embodiment 1 of the present disclosure includes the steps of: forming the insulating film 50 on the semiconductor substrate 2; forming the N-type semiconductor layer 55 on the insulating film 50; and heat-treating the semiconductor substrate 2 on which the N-type semiconductor layer 55 is formed, and diffusing N-type impurities in solid phase from the N-type semiconductor layer 55 to the semiconductor substrate 2, to form the N+ type regions 411, 421 serving as a source or drain of the MOS transistor 3.

Thus, the N+ type regions 411, 421 can be formed by the solid-phase diffusion of the N-type impurities from the N-type semiconductor layer 55 to the semiconductor substrate 2 via the insulating film 50. By introducing the N-type impurities by solid-phase diffusion instead of ion-implantation, the N+ type regions 411, 421 can be formed thinly, and diffusion of the N-type impurities in the lateral direction can be suppressed.

Since diffusion of the N-type impurities in the lateral direction can be suppressed, the occurrence of a short channel effect can be suppressed in the MOS transistor 3, and the effective gate length can be increased. Furthermore, since diffusion of the N-type impurities in the lateral direction can be suppressed, the N+ type regions 411, 421 of high concentration can be formed. Consequently, a contact resistance of each of the source region 41 and the drain region 42 can be reduced.

### Embodiment 2

The technique of the present technology may be applied to a MOS transistor with a groove-gate structure called FinFET, for example.

### (Example of Configuration of Semiconductor Device)

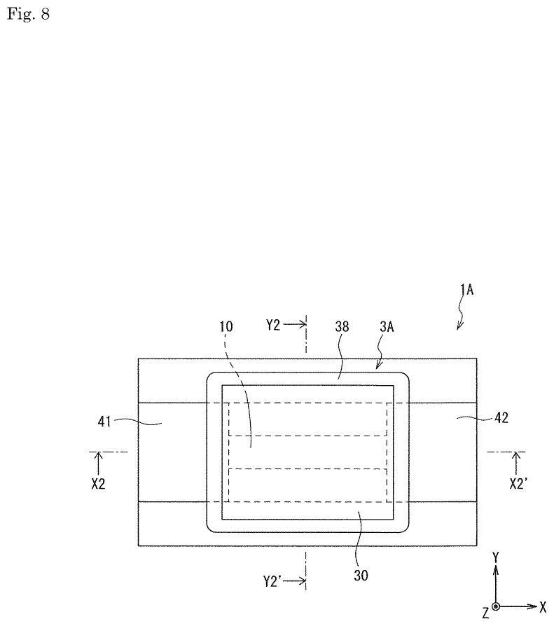

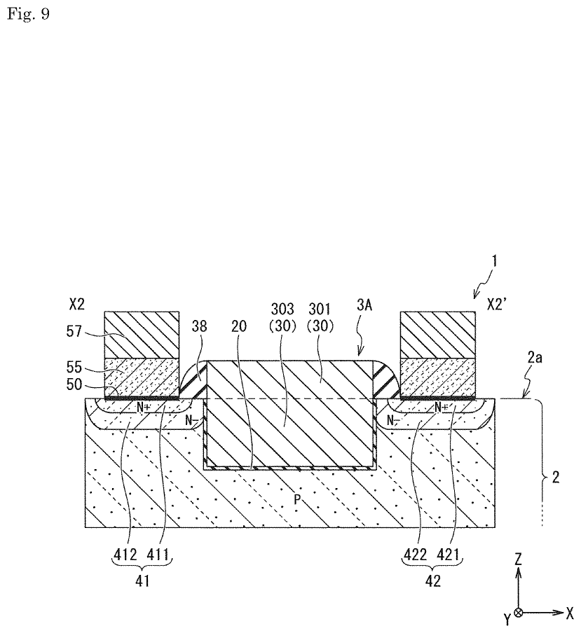

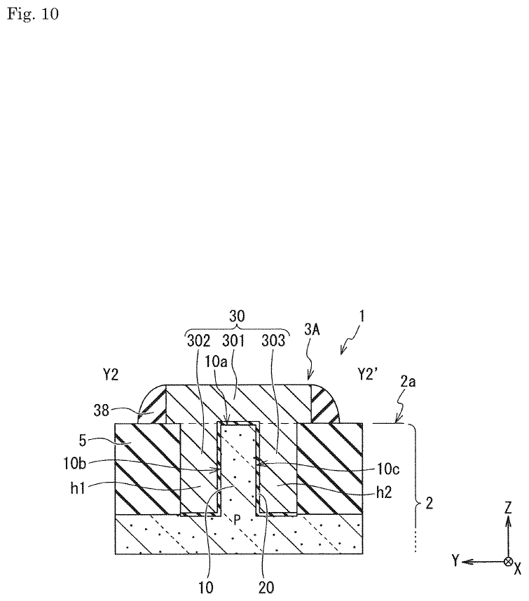

FIG. 8 is a plan view schematically showing a configuration example of a semiconductor device 1A according to Embodiment 2 of the present disclosure. FIGS. 9 and 10 are cross-sectional views schematically showing a configuration example of the semiconductor device 1A according to Embodiment 2 of the present disclosure. FIG. 9 shows a cross section of the plan view shown in FIG. 8, taken along line X2-X2′. FIG. 10 shows a cross section of the plan view shown in FIG. 8, taken along line Y2-Y2′. Note that FIG. 8 omits the illustration of the N-type semiconductor layer 55 and the contact electrode 57 shown in FIG. 9.

In the semiconductor device 1A shown in FIGS. 8 to 10, the semiconductor region 10 is a section formed by etching a part on the front surface 2a side of the semiconductor substrate 2. The conductivity type of the semiconductor region 10 is P type. The shape of the semiconductor region 10 is, for example, a fin (Fin) shape. The semiconductor region 10 has a shape that is, for example, longer in the X-axis direction and shorter in the Y-axis direction.

In the Y-axis direction, a first trench h1 is provided on one side of the semiconductor region 10, and a second trench h2 is provided on the other side of the semiconductor region 10. Each of the first trench h1 and the second trench h2 is opened on the front surface 2a side of the semiconductor substrate 2.

The gate insulating film 20 is provided so as to cover a top surface 10a of the semiconductor region 10, a first side surface 10b and a second side surface 10c of the semiconductor region 10, a bottom surface of the first trench h1, and a bottom surface of the second trench h2 continuously. The first side surface 10b of the semiconductor region 10 is located on one side of the top surface 10a in the Y-axis direction. The second side surface 10c of the semiconductor region 10 is located on the other side of the top surface 10a in the Y-axis direction. The gate insulating film 20 is composed of, for example, a SiO₂ film.

The gate electrode 30 covers the semiconductor region 10 via the gate insulating film 20. For example, the gate electrode 30 has a first section 301, which faces the top surface 10a of the semiconductor region 10 via the gate insulating film 20, a second section 302, which faces the first side surface 10b of the semiconductor region 10 via the gate insulating film 20, and the third section 303, which faces the second side surface 10c of the semiconductor region 10 via the gate insulating film 20. The second section 302 and the third section 303 are connected to a lower surface of the first section 301.

The second section 302 of the gate electrode 30 is arranged in the first trench h1. The third section 303 of the gate electrode 30 is arranged in the second trench h2. The semiconductor region 10 is sandwiched, in the Y-axis direction, between the second section 302 arranged in the first trench h1 and the third section 303 arranged in the second trench h2.

Thus, the gate electrode 30 can apply a gate voltage to the top surface 10a, the first side surface 10b, and the second side surface 10c of the semiconductor region 10 simultaneously. That is, the gate electrode 30 can apply a gate voltage simultaneously to the semiconductor region 10 in a total of three directions; from above, from the left, and from the right. Thus, the gate electrode 30 can completely deplete the semiconductor region 10. Note that the gate electrode 30 is composed of, for example, a polysilicon (Poly-Si) film doped with impurities.

Due to the shape of a MOS transistor 3A according to Embodiment 2 of the present disclosure (an example of “field effect transistor” of the present disclosure) in which the second section 302 and the third section 303 of the gate electrode 30 are arranged in the first trench h1 and the second trench h2, respectively, the MOS transistor 3A may also be referred to as a MOS transistor with a groove-gate structure. The MOS transistor 3A may also be referred to as a FinFET (Fin Field Effect Transistor) because the semiconductor region 10 has the Fin shape. Alternatively, due to the two shapes described above, the MOS transistor 3A may also be referred to as a grooved FinFET.

As with Embodiment 1, in Embodiment 2 as well, the N+ type region 411 of the source region 41 of the MOS transistor 3A and the N+ type region 421 of the drain region 42 of the same are formed by solid-diffusion of N-type impurities from the N-type semiconductor layer 55 into the semiconductor substrate 2 via the insulating film 50. The peak concentrations of the N-type impurities in the N+ type regions 411, 421 are 1×10²⁰/cm³ or more. Thus, the N-type semiconductor layer 55 is ohmically connected to each of the N+ type regions 411, 421 via the insulating film 50.

Also, the contact electrode 57 and the N-type semiconductor layer 55 are ohmically connected to each other, and the N-type semiconductor layer 55 and the N+ type regions 411, 421 are ohmically connected to each other. Therefore, ohmic connections are made between the contact electrode 57 and the N+ type region 411 and between the contact electrode 57 and the N+ type region 421.

Furthermore, end portions of the N+ type regions 411, 421 where the concentration of the N-type impurities is 1×10¹⁷/cm³ or less are present within 0.1 μm from the front surface 2a of the semiconductor substrate 2. That is, the depth of the N+ type regions 411, 421 from the front surface 2a is 0.1 μm or less. The N+ type regions 411, 421 are formed very thinly in the vicinity of the front surface 2a of the semiconductor substrate 2.

### (Method of Manufacturing Semiconductor Device)

The steps of a method of manufacturing the semiconductor device 1 according to Embodiment 2 of the present disclosure will be sequentially described next.

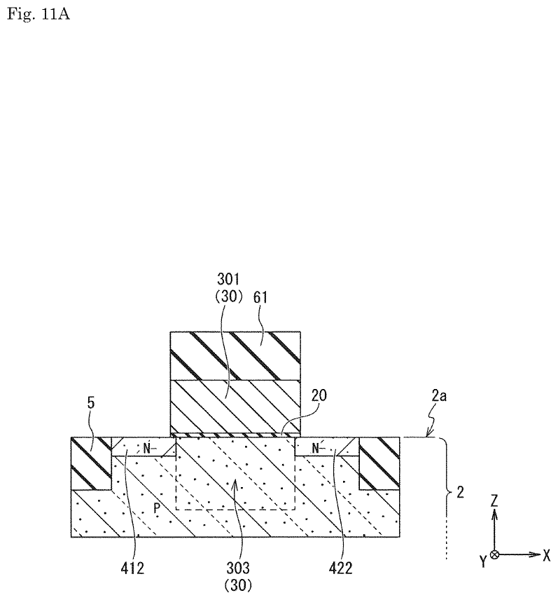

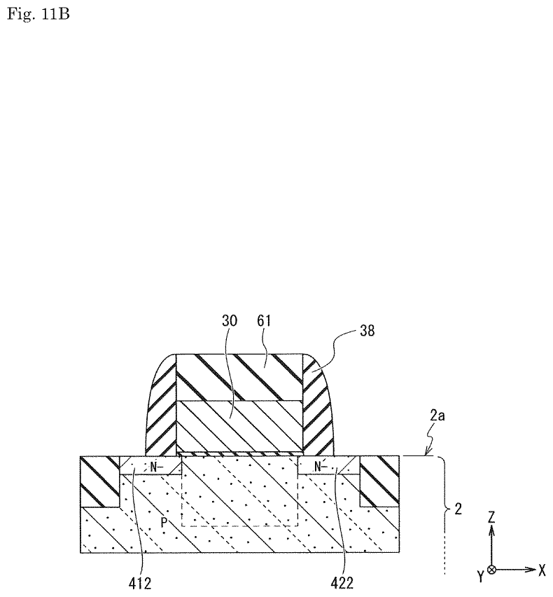

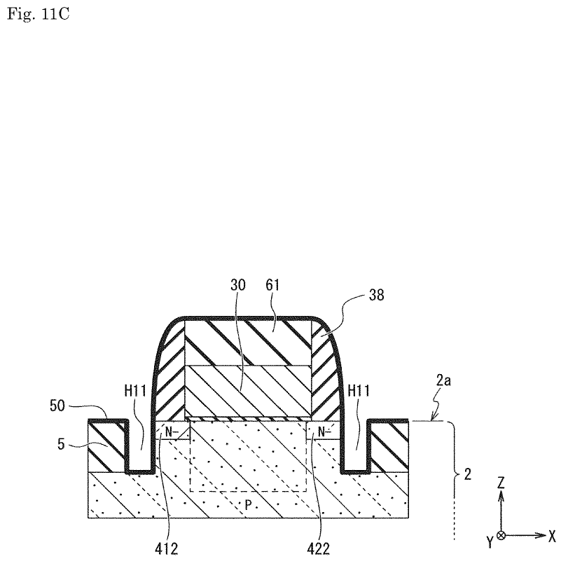

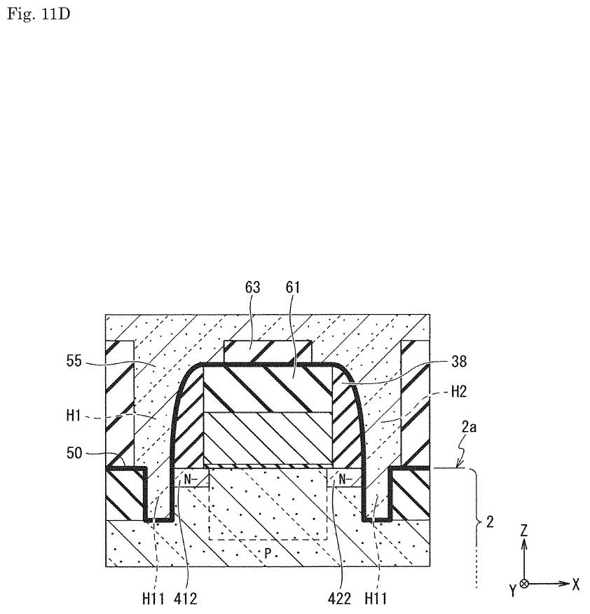

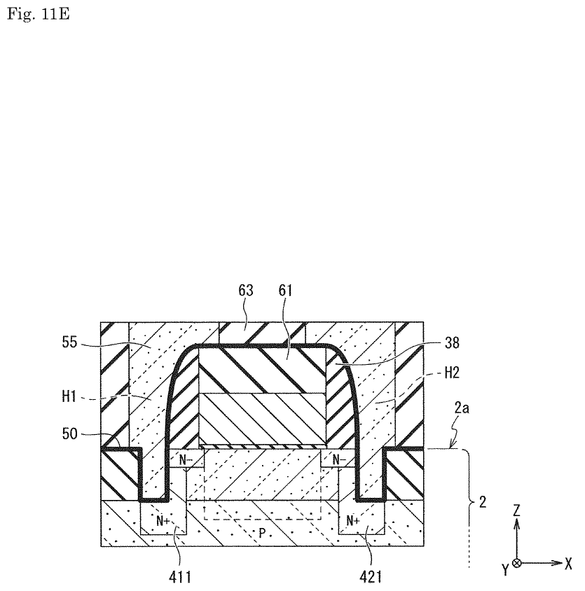

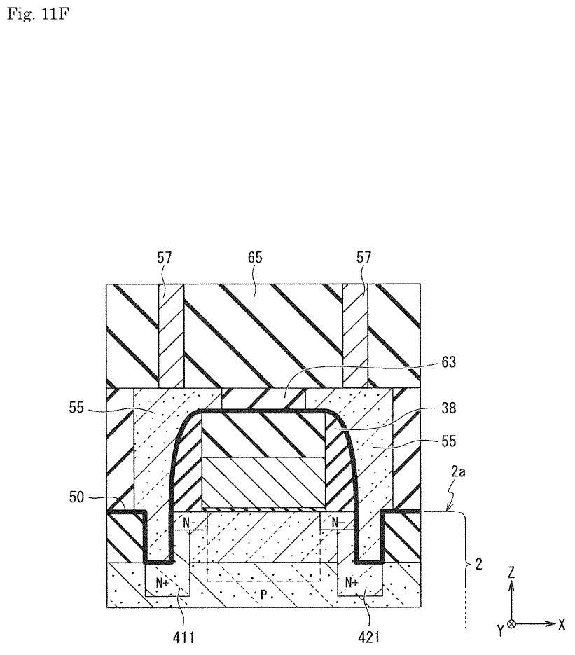

FIGS. 11A to 11F are cross-sectional views sequentially showing the steps of the method of manufacturing the semiconductor device 1A according to Embodiment 2 of the present disclosure. Each of the cross sections shown in FIGS. 11A to 11F corresponds to the X2-X2-′ cross section (X-Z cross section) shown in FIG. 9.

In FIG. 11A, the manufacturing device forms the first trench h1 and the second trench h2 by etching the front surface 2a side of the semiconductor substrate 2 (see FIG. 10). As a result, the semiconductor region 10 having the Fin shape can be formed in the semiconductor substrate 2 (see FIG. 10). Next, the manufacturing device thermally oxidizes the semiconductor substrate 2, and forms the gate insulating film 20 on the top surface 10a, the first side surface 10b, and the second side surface 10c of the semiconductor region 10 (see FIG. 10).

Next, the manufacturing device uses a CVD method to form a polysilicon film on the gate insulating film 20. The first trench h1 and the second trench h2 are filled with the polysilicon film. Next, the manufacturing device forms the hard mask 61 on the polysilicon film. The hard mask 61 has a shape that covers the region where the gate electrode 30 is formed, but is open in the other regions. The hard mask 61 is composed of, for example, a SiO₂ film. Next, the manufacturing device removes the polysilicon film through etching, by using the hard mask 61 as a mask. As a result, the manufacturing device forms the gate electrode 30.

Next, the manufacturing device ion-implants the N-type impurities such as phosphorous (P) or arsenic (As) on the front surface 2a side of the semiconductor substrate 2 by using the hard mask 61 as a mask. After the ion-implantation, the semiconductor substrate 2 is heat-treated, and the ion-implanted N-type impurities are activated. As a result, the N− type region 412 of the source region 41 and the N− type region 422 of the drain region 42 are formed in self-alignment with respect to the gate electrode 30. Note that the heat treatment for forming the N− type regions 412, 422 may not be performed at that moment but may be performed concurrently with heat treatment in the subsequent step (e.g., heat treatment for forming the N+ type regions 411, 412).

Next, the manufacturing device deposits the SiO₂ film and SiN film sequentially by means of, for example, the CVD method, and etches back the deposited films. Accordingly, the manufacturing device forms the sidewall insulating film 38 on a side surface of the gate electrode 30, as shown in FIG. 11B.

Next, using the hard mask 61 and the sidewall insulating film 38 as masks, the manufacturing device etches the front surface 2a side of the semiconductor substrate 2 (i.e., forms a recess). Consequently, as shown in FIG. 11C, the manufacturing device forms recess portions H11 in a region where the source is formed and a region where the drain is formed, respectively, in the semiconductor substrate 2. Etching conditions are adjusted in such a manner that the depth of the recess portions H11 from the front surface 2a is the same (or roughly the same) as the thickness of the element separation layer 5 from the front surface 2a.

Next, the manufacturing device forms the insulating film 50 on the front surface 2a of the semiconductor substrate 2. For example, the manufacturing device forms the insulating film 50 into a thickness of 5 Å or more and 15 Å or less by means of an ALD method. The insulating film 50 is a SiN film or a SiO₂ film. The insulating film 50 is provided in a continuous manner on the front surface 2a of the semiconductor substrate 2 (including bottom surfaces and inner side surfaces of the recess portions H11), the sidewall insulating film 38, and the hard mask 61.

Next, in FIG. 11D, the manufacturing device forms the first interlayer insulating film 63 on the front surface 2a of the semiconductor substrate 2 by means of the CVD method. Next, the manufacturing device etches part of the first interlayer insulating film 63, and forms the opening portions H1, H2 continuous to the recess portions H11, on the recess portion H11 formed in the recess step.

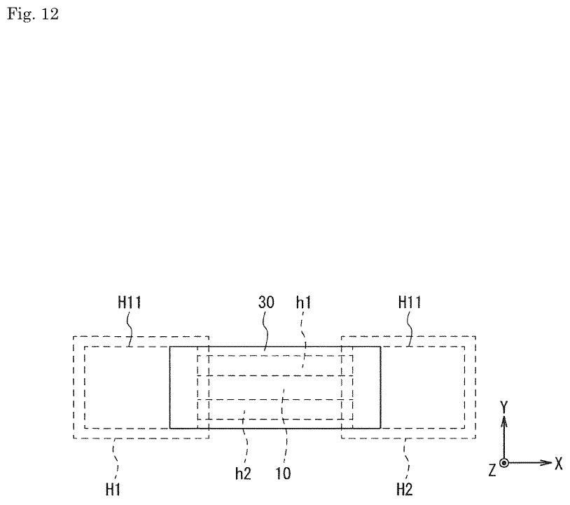

FIG. 12 is a plan view schematically showing the positional relationship among the recess portions H11 (recess patterns) formed in the step shown in FIG. 11C, the opening portions H1, H2 formed in the step shown in FIG. 11D, and the gate electrode 30. As shown in FIG. 12, the opening portions H1, H2 are formed so as to cover the entire recess portions H11 (recess patterns) in plan view. The opening portions H1, H2 are also formed in self-alignment with respect to the gate electrode 30.

Next, as shown in FIG. 11D, the manufacturing device deposits the N-type semiconductor layer 55 doped with the N-type impurities over the entire upper part of the front surface 2a of the semiconductor substrate 2 by the CVD method, to fill the opening portions H1, H2. As described above, the N-type semiconductor layer 55 is, for example, polysilicon, amorphous silicon, or SiGe. Also, the concentration of the N-type impurities in the N-type semiconductor layer 55 is, for example, 1×10²⁰/cm³ or more. Examples of the N-type impurities included in the N-type semiconductor layer 55 include arsenic (As), phosphorous (P), or both.

Next, the manufacturing device heat-treats the N-type semiconductor layer 55 and the semiconductor substrate 2 (i.e., the entire substrate), and diffuses the N-type impurities in solid phase from the N-type semiconductor layer 55 to the semiconductor substrate 2 via the insulating film 50. The conditions for the heat treatment are, for example, that the heat treatment temperature is 1015° C. and the heat treatment duration is 10 minutes. In this manner, as shown in FIG. 11E, the manufacturing device forms the N+ type region 411 of the source region 41 and the N+ type region 421 of the drain region 42.

Next, the manufacturing device etches back the N-type semiconductor layer 55. Accordingly, the N-type semiconductor layer 55 is separated into a section connected to the N+ type region 411 (source pad) and a section connected to the N+ type region 412 (drain pad).

Next, as shown in FIG. 11F, the manufacturing device forms the second interlayer insulating film 65 over the entire upper part of the front surface 2a of the semiconductor substrate 2 by the CVD method. Next, the manufacturing device partially etches the second interlayer insulating film 65 to form the source opening portion and the drain opening portion on the second interlayer insulating film 65.

Next, the manufacturing device sequentially deposits the barrier metal and tungsten (W) over the entire upper part of the front surface 2a of the semiconductor substrate 2 by means of, for example, the CVD method or sputtering method, performs CMP treatment on the tungsten (W) film, to expose the second interlayer insulating film 65 from below the tungsten (W) film. Accordingly, the manufacturing device forms the contact electrode 57 on each of the source pad and the drain pad. The semiconductor device 1A according to Embodiment 2 is completed through the steps described above.

### Advantageous Effects of Embodiment 2

The MOS transistor 3A and the method of manufacturing the same according to Embodiment 2 achieve the same effects as the MOS transistor 3 and the method of manufacturing the same according to Embodiment 1. For example, as a result of solid-phase diffusion of the N-type impurities from the N-type semiconductor layer 55 to the semiconductor substrate 2 via the insulating film 50, the N+ type regions 411, 421 can be formed. By introducing the N-type impurities by solid-phase diffusion instead of ion-implantation, the N+ type regions 411, 421 can be formed thinly, and diffusion of the N-type impurities in the lateral direction can be suppressed.

Since diffusion of the N-type impurities in the lateral direction can be suppressed, the occurrence of a short channel effect can be suppressed in the MOS transistor 3A, and the effective gate length can be increased. Furthermore, since diffusion of the N-type impurities in the lateral direction can be suppressed, the N+ type regions 411, 421 of high concentration can be formed. Consequently, a contact resistance of each of the source region 41 and the drain region 42 can be reduced.

Further, the MOS transistor 3A is a FinFET. In other words, the gate electrode 30 can simultaneously apply a gate voltage to the semiconductor region 10 in a total of three directions; from above, from the left, and from the right. Thus, the gate electrode 30 can completely deplete the semiconductor region 10, and an S value indicating subthreshold characteristics of the MOS transistor 3A can be reduced. A high-speed switching operation of the MOS transistor 3A becomes possible.

Moreover, in this example, the N-type semiconductor layer 55 is arranged inside the recess portions H11 formed by being recessed in the semiconductor substrate 2. Therefore, the N-type semiconductor layer 55 on the N+ type region 411 functions as a high-concentration layer of the source region 41 as with the N+ type region 411. The N-type semiconductor layer 55 on the N+ type region 421 functions as a high-concentration layer of the drain region 42 as with the N+ type region 421. Due to the N-type semiconductor layer 55 embedded in the recess portions H11, the depth of the high-concentration layer of the source region 41 and the depth of the high-concentration layer of the drain region 42 are increased to become approximately the same depth as, for example, the element separation layer 5. Accordingly, an on-resistance of the MOS transistor 3A can be reduced.

### Embodiment 3

### (Example of Imaging Device)

The semiconductor device 1 according to the semiconductor device 1 according to Embodiment 1 or the semiconductor device 1A according to Embodiment 2 can be applied to an imaging device. An example of the imaging device to which the semiconductor devices 1, 1A are applied will be described hereinafter.

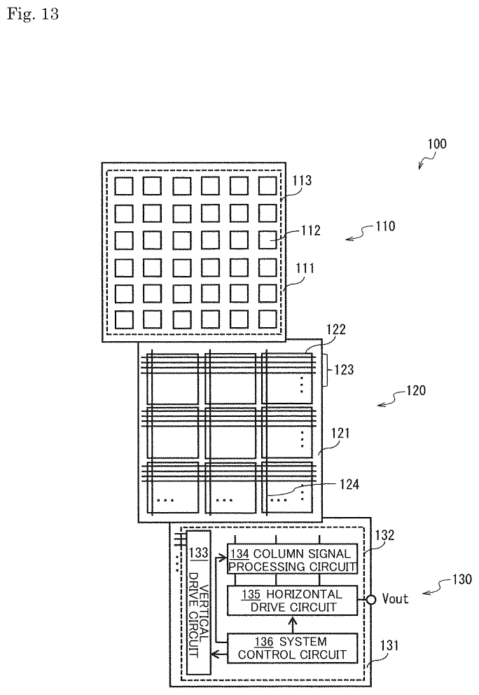

FIG. 13 is a schematic diagram showing a configuration example of an imaging device 100 according to Embodiment 3 of the present disclosure. The imaging device 100 has a first substrate unit 110, a second substrate unit 120, and a third substrate unit 130. The imaging device 100 is an imaging device having a three-dimensional structure configured by bonding the first substrate unit 110, the second substrate unit 120, and the third substrate unit 130. The first substrate unit 110, the second substrate unit 120, and the third substrate unit 130 are laminated in order.

The first substrate unit 110 has a semiconductor substrate 111, and a plurality of sensor pixels 112 provided on the semiconductor substrate 111. The plurality of sensor pixels 112 perform photoelectric conversion. The plurality of sensor pixels 112 are provided in a matrix shape in a pixel region 113 of the first substrate unit 110. The second substrate unit 120 has a semiconductor substrate 121, a readout circuit 122 provided on the semiconductor substrate 121, a plurality of pixel drive lines 123 provided on the semiconductor substrate 121 and extending in a row direction, and a plurality of vertical signal lines 124 provided on the semiconductor substrate 121 and extending in a column direction. The readout circuit 122 outputs pixel signals based on electric charges output from the sensor pixels 112. One readout circuit 122 is provided for every four sensor pixels 112.

The third substrate unit 130 has a semiconductor substrate 131, and a logic circuit 132 provided on the semiconductor substrate 131. The logic circuit 132 has a function of processing the pixel signals and has, for example, a vertical drive circuit 133, a column signal processing circuit 134, a horizontal drive circuit 135, and a system control circuit 136.

The vertical drive circuit 133, for example, selects the plurality of sensor pixels 112 in order by rows. The column signal processing circuit 134, for example, performs Correlated Double Sampling (CDS) processing on the pixel signal that is output from each of the sensor pixels 112 selected by the vertical drive circuit 133. The column signal processing circuit 134, for example, extracts the signal levels of the pixel signals by performing the CDS processing, and holds pixel data corresponding to the light-receiving amount of each sensor pixel 112. The horizontal drive circuit 135, for example, outputs the pixel data held by the column signal processing circuit 134 to the outside sequentially. The system control circuit 136, for example, controls the drive of each block inside the logic circuit 132 (the vertical drive circuit 133, the column signal processing circuit 134, and the horizontal drive circuit 135).

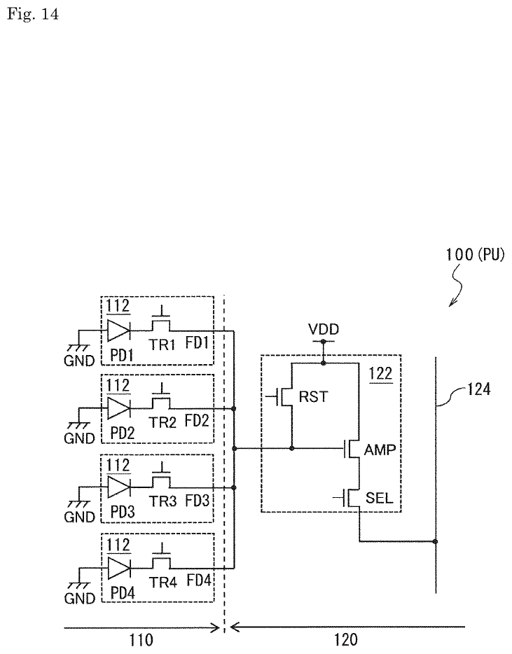

FIG. 14 is a circuit diagram showing a configuration example of a pixel unit PU according to Embodiment 3 of the present disclosure. As shown in FIG. 14, in the imaging device 100, four sensor pixels 112 are electrically connected to one readout circuit 122 to form one pixel unit PU. The four sensor pixels 112 share the one readout circuit 122, and each output from the four sensor pixels 112 is input to the shared readout circuit 122.

The respective sensor pixels 112 have common constituent elements. In FIG. 14, in order to distinguish the constituent elements of the respective sensor pixels 112 from each other, an identification number (1, 2, 3, 4) is added to the ends of reference numerals (e.g., PD, TG, FD, which will be described later) of the constituent elements of the respective sensor pixels 112. In cases below in which it is not necessary to distinguish the constituent elements of the respective sensor pixels 112 from each other, the identification numbers at the ends of the reference numerals of the constituent elements of the respective sensor pixel 112 will be omitted.

Each of the sensor pixels 112 has, for example, a photodiode PD (an example of the “photoelectric conversion element” of the present disclosure), a transfer transistor TR connected electrically to the photodiode PD, and a floating diffusion FD for temporarily holding an electric charge output from the photodiode PD via the transfer transistor TR. The photodiode PD performs photoelectric conversion to generates an electric charge corresponding to the light-receiving amount. A cathode of the photodiode PD is electrically connected to a source of the transfer transistor TR, and an anode of the photodiode PD is electrically connected to a reference potential line (e.g., the ground). A drain of the transfer transistor TR is electrically connected to the floating diffusion FD, a gate electrode of the transfer transistor TR is electrically connected to the pixel drive line 123. The transfer transistor TR is, for example, a complementary metal oxide semiconductor (CMOS) transistor.

The floating diffusions FD of the respective sensor pixels 112 that share one readout circuit 122 are electrically connected to each other and are also electrically connected to an input terminal of the common readout circuit 122. The readout circuit 122 includes, for example, an amplification transistor AMP, a reset transistor RST, and a selection transistor SEL. Also, the selection transistor SEL may be omitted if necessary.

A source of the reset transistor RST (the input terminal of the readout circuit 122) is electrically connected to the floating diffusion FD, and a drain of the reset transistor RST is electrically connected to a power line VDD and a drain of the amplification transistor AMP. A gate electrode of the reset transistor RST is electrically connected to the pixel drive line 123 (see FIG. 13). A source of the amplification transistor AMP is electrically connected to a drain of the selection transistor SEL, and a gate electrode of the amplification transistor AMP is electrically connected to the source of the reset transistor RST. A source of the selection transistor SEL (an output terminal of the readout circuit 122) is electrically connected to the vertical signal line 124, and a gate electrode of the selection transistor SEL is electrically connected to the pixel drive line 123 (see FIG. 13).

When the transfer transistor TR is turned on, the transfer transistor TR transfers the electric charge of the photodiode PD to the floating diffusion FD. The reset transistor RST resets the potential of the floating diffusion FD to a predetermined potential. When the reset transistor RST is turned on, the potential of the floating diffusion FD is reset to the potential of the power line VDD. The selection transistor SEL controls an output timing of a pixel signal from the readout circuit 122.

The amplification transistor AMP generates a voltage signal serving as the pixel signal, in accordance with a level of the electric charge held in the floating diffusion FD. The amplification transistor AMP constitutes a source follower type amplifier and outputs the pixel signal having a voltage corresponding to the level of electric charge generated by the photodiode PD. When the selection transistor SEL is turned on, the amplification transistor AMP amplifies the potential of the floating diffusion FD and outputs a voltage corresponding to said potential to the column signal processing circuit 134 via the vertical signal line 124.

In Embodiment 3 of the present disclosure, the MOS transistor 3 described in Embodiment 1 or the MOS transistor 3A described in Embodiment 2 is used as at least one of the reset transistor RST, the amplification transistor AMP, the transfer transistor TR, and the selection transistor SEL.

For example, as shown in FIG. 14, the transfer transistor TR is provided in the first substrate unit 110. The MOS transistor 3 described in Embodiment 1 or the MOS transistor 3A described in Embodiment 2 may be used as the transfer transistor TR. In this case, the semiconductor substrate 111 is equivalent to the semiconductor substrate 2 described in Embodiments 1, 2.

Also, as shown in FIG. 14, the reset transistor RST, the amplification transistor AMP, and the selection transistor SEL are provided in the second substrate unit 120. The MOS transistor 3 described in Embodiment 1 or the MOS transistor 3A described in Embodiment 2 may be used as at least one of the reset transistor RST, the amplification transistor AMP and the selection transistor SEL.

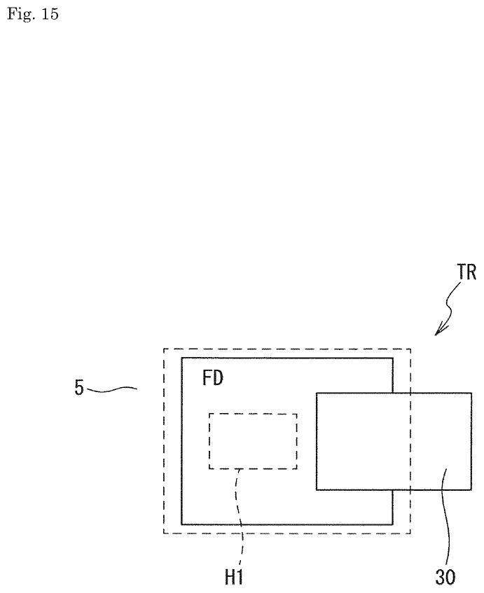

Note that FIG. 15 is a plan view schematically showing the positional relationship between the opening portion H1 and the gate electrode 30 that is obtained when the MOS transistor 3 described in Embodiment 1 is used as the transfer transistor TR of the pixel unit PU. In the example shown in FIG. 15, the floating diffusion FD is equivalent to the source region of the MOS transistor 3. As shown in FIG. 15, in the embodiments of the present disclosure, the opening portion H1 opened on the source region (the floating diffusion FD in this example) may not be formed in self-alignment with respect to the gate electrode 30.

As described above, the imaging device 100 according to Embodiment 3 of the present invention has the photodiode PD, and a semiconductor device for reading out an electric charge obtained by photoelectric conversion by the photodiode PD. As at least a part of this semiconductor device, the imaging device 100 has the semiconductor device 1 (or the semiconductor device 1A). The semiconductor device 1 (or the semiconductor device 1A) can suppress the occurrence of a short channel effect and increase the effective gate length because diffusion of the N-type impurities in the lateral direction is suppressed. In addition, since diffusion of the N-type impurities in the lateral direction is suppressed, the source region 41 and the drain region 42 of high concentration can be formed, and a contact resistance of each of the source region 41 and the drain region 42 can be reduced. As a result, the readout performance of the imaging device 100 can be improved.

### Other Embodiments

While the present disclosure has been described on the basis of the embodiments and modifications as described above, the descriptions and drawings that constitute parts of the present disclosure should not be understood as limiting the present disclosure. Various alternative embodiments, examples, and operable techniques will be apparent to those skilled in the art from the present disclosure. For example, the use of the “semiconductor devices” of the present disclosure is not limited to the imaging device 100. The “semiconductor devices” of the present disclosure may be used in electronic devices other than the imaging device 100.

Thus, needless to say, the present technology includes various embodiments and the like that are not described herein. At least one of various omissions, substitutions and modifications of constituent elements may be performed without departing from the gist of the embodiments and modification examples described above. Furthermore, the advantageous effects described in the present description are merely exemplary and not intended to be limiting, and other advantageous effects may be exerted as well.

The present disclosure can also take the following configurations.

(1)

A semiconductor device, comprising:
a semiconductor substrate; and
a field effect transistor provided on a first main surface side of the semiconductor substrate,
wherein the field effect transistor includes:
an N-type region provided on the first main surface side of the semiconductor substrate and serving as at least a part of a source region or at least a part of a drain region;
an insulating film provided on the N-type region; and
an N-type semiconductor layer provided on the N-type region via the insulating film.
   (2)

The semiconductor device according to (1) above, wherein the insulating film has a film thickness of 5 Å or more and 15 Å or less.

(3)

The semiconductor device according to (1) or (2) above, wherein a peak concentration of N-type impurities in the N-type region is 1×10²⁰/cm³ or more, and
an end portion of the N-type region where a concentration of the N-type impurities is 1×10¹⁷/cm³ or less is present within 0.1 μm from the first main surface of the semiconductor substrate.
   (4)

The semiconductor device according to any one of (1) to (3) above, wherein a concentration of N-type impurities in the N-type semiconductor layer is 1×10²⁰/cm³ or more.

(5)

The semiconductor device according to (4) above, wherein the N-type semiconductor layer is polysilicon, amorphous silicon, or SiGe.

(6)

The semiconductor device according to any one of (1) to (5) above, wherein the field effect transistor includes:
a semiconductor region in which a channel is formed;
a gate electrode covering the semiconductor region;
a gate insulating film arranged between the semiconductor region and the gate electrode; and
a sidewall insulating film arranged on a side surface of the gate electrode, and
the N-type semiconductor layer covers at least a part of the sidewall insulating film.
   (7)

The semiconductor device according to any one of (1) to (5) above, wherein the field effect transistor includes:
a semiconductor region in which a channel is formed;
a gate electrode covering the semiconductor region; and
a gate insulating film arranged between the semiconductor region and the gate electrode,
the semiconductor region includes:
a top surface;
a first side surface located on one side of the top surface in a gate width direction of the gate electrode; and
a second side surface located on the other side of the top surface in the gate width direction, and
the gate electrode includes:
a first section facing the top surface via the gate insulating film;
a second section facing the first side surface via the gate insulating film; and
a third section facing the second side surface via the gate insulating film.
   (8)

The semiconductor device according to any one of (1) to (7) above, wherein the N-type semiconductor layer is ohmically connected to the N-type region via the insulating film.

(9)

A method of manufacturing a semiconductor device, the method comprising the steps of:
forming an insulating film on a semiconductor substrate;
forming an N-type semiconductor layer on the insulating film; and
heat-treating the semiconductor substrate on which the N-type semiconductor layer is formed, and diffusing N-type impurities in solid phase from the N-type semiconductor layer to the semiconductor substrate, to form an N-type region serving as at least a part of a source region or at least a part of a drain region.
   (10)

An imaging device, comprising:
a photoelectric conversion element; and
a semiconductor device for reading out an electric charge obtained by photoelectric conversion by the photoelectric conversion element,
wherein the semiconductor device includes:
a semiconductor substrate; and
a field effect transistor provided on a first main surface side of the semiconductor substrate, and
the field effect transistor includes:
an N-type region provided on the first main surface side of the semiconductor substrate and serving as at least a part of a source region or at least a part of a drain region;
an insulating film provided on the N-type region; and
an N-type semiconductor layer provided on the N-type region via the insulating film.

### REFERENCE SIGNS LIST

1, 1A Semiconductor device
2 Semiconductor substrate
2a Front surface
2b Rear surface
3, 3A MOS transistor
5 Element separation layer
10 Semiconductor region
10a Top surface
10b First side surface
10c Second side surface
20 Gate insulating film
30 Gate electrode
38 Sidewall insulating film
41 Source region
42 Drain region
50 Insulating film
55 N-type semiconductor layer
57 Contact electrode
61 Hard mask
63 First interlayer insulating film
65 Second interlayer insulating film
100 Imaging device
110 First substrate unit
111 Semiconductor substrate
112 Sensor pixel
113 Pixel region
120 Second substrate unit
121 Semiconductor substrate
122 Readout circuit
123 Pixel drive line
124 Vertical signal line
130 Third substrate unit
131 Semiconductor substrate
132 Logic circuit
133 Vertical drive circuit
134 Column signal processing circuit
135 Horizontal drive circuit
136 System control circuit
301 First section
302 Second section
303 Third section
411, 421 N+ type region
412, 422 N− type region
AMP Amplification transistor
FD Floating diffusion
h1 First trench
h2 Second trench
H1, H2 Opening portion
H11 Recess portion
PD Photodiode
PU Pixel unit
RST Reset transistor
SEL Selection transistor
TR Transfer transistor
VDD Power line

1. A semiconductor device, comprising:
a semiconductor substrate; and
a field effect transistor provided on a first main surface side of the semiconductor substrate,
wherein the field effect transistor includes:
an N-type region provided on the first main surface side of the semiconductor substrate and serving as at least a part of a source region or at least a part of a drain region;
an insulating film provided on the N-type region; and
an N-type semiconductor layer provided on the N-type region via the insulating film.

2. The semiconductor device according to claim 1, wherein the insulating film has a film thickness of 5 Å or more and 15 Å or less.

3. The semiconductor device according to claim 1, wherein a peak concentration of N-type impurities in the N-type region is 1×10²⁰/cm³ or more, and
an end portion of the N-type region where a concentration of the N-type impurities is 1×10¹⁷/cm³ or less is present within 0.1 μm from the first main surface of the semiconductor substrate.

4. The semiconductor device according to claim 1, wherein a concentration of N-type impurities in the N-type semiconductor layer is 1×10²⁰/cm³ or more.

5. The semiconductor device according to claim 4, wherein the N-type semiconductor layer is polysilicon, amorphous silicon, or SiGe.

6. The semiconductor device according to claim 1, wherein the field effect transistor includes:
a semiconductor region in which a channel is formed;
a gate electrode covering the semiconductor region;
a gate insulating film arranged between the semiconductor region and the gate electrode; and
a sidewall insulating film arranged on a side surface of the gate electrode, and
the N-type semiconductor layer covers at least a part of the sidewall insulating film.

7. The semiconductor device according to claim 1, wherein the field effect transistor includes:
a semiconductor region in which a channel is formed;
a gate electrode covering the semiconductor region; and
a gate insulating film arranged between the semiconductor region and the gate electrode,
the semiconductor region includes:
a top surface;
a first side surface located on one side of the top surface in a gate width direction of the gate electrode; and
a second side surface located on the other side of the top surface in the gate width direction, and
the gate electrode includes:
a first section facing the top surface via the gate insulating film;
a second section facing the first side surface via the gate insulating film; and
a third section facing the second side surface via the gate insulating film.

8. The semiconductor device according to claim 1, wherein the N-type semiconductor layer is ohmically connected to the N-type region via the insulating film.

9. A method of manufacturing a semiconductor device, the method comprising the steps of:
forming an insulating film on a semiconductor substrate;
forming an N-type semiconductor layer on the insulating film; and
heat-treating the semiconductor substrate on which the N-type semiconductor layer is formed, and diffusing N-type impurities in solid phase from the N-type semiconductor layer to the semiconductor substrate, to form an N-type region serving as at least a part of a source region or at least a part of a drain region.

10. An imaging device, comprising:
a photoelectric conversion element; and
a semiconductor device for reading out an electric charge obtained by photoelectric conversion by the photoelectric conversion element,
wherein the semiconductor device includes:
a semiconductor substrate; and
a field effect transistor provided on a first main surface side of the semiconductor substrate, and
the field effect transistor includes:
an N-type region provided on the first main surface side of the semiconductor substrate and serving as at least a part of a source region or at least a part of a drain region;
an insulating film provided on the N-type region; and
an N-type semiconductor layer provided on the N-type region via the insulating film.
